(19) United States
(12) Patent Application Publication
(10) Pub. No.: US 2011/0309395 A1
(43) Pub. Date: Dec. 22, 2011

(54) COLOR VARIABLE LIGHT EMITTING DEVICE

(75) Inventor: Johannes Lambrecht Marinus VAN DEN BERGE, Mijdrecht (NL)

(73) Assignee: KONINKLIJKE PHILIPS ELECTRONICS N.V., EINDHOVEN (NL)

(21) Appl. No.: 12/919,244

(22) PCT Filed: Feb. 27, 2009
(86) PCT No.: PCT/IB2009/050802

§ 371 Date: Nov. 22, 2010

(30) Foreign Application Priority Data
Mar. 7, 2008 (EP) 08152434.0

(51) Int. Cl. H01L 33/50

(52) U.S. Cl. 257/98; 257/E33.06

(57) ABSTRACT

The present invention relates to a color variable light emitting device (100; 200; 300; 400) comprising at least one light source (101; 201; 303; 401) and at least one deformable element (102; 202; 301; 402). The deformable element (102; 202; 301; 402) comprises particles of at least one wavelength converting material (103; 203; 305; 403) and the element (102; 202; 301; 402) is arranged to receive light from the at least one light source (101; 201; 303; 401) and to convert it into light of a different wavelength. Since the element comprising the wavelength converting material(s) is deformable, the thickness of the element can be varied. This thickness variation allows for the wavelength converting material, and hence also the color, to be tuned.

### TECHNICAL FIELD

The present invention relates to a color variable light emitting device comprising at least one light source and at least one deformable element.

### BACKGROUND OF THE INVENTION

In order to generate white light or light of any other color, lighting systems utilizing multiple light emitting diodes (LEDs) of different colors in combination with wavelength converting material; i.e. phosphors are often used. Improvements in efficiency and color quality in such phosphor based light emitting devices are constantly being developed.

Most LEDs contain only a single internal die and can produce one primary color or optical wavelength. Typically, an RGB (Red Green Blue) LED setup is utilized to generate various colors of light. By mixing the three primary colors red, green and blue, an RGB LED, also referred to as a “full color” LED, can produce a vast array of colors, and when properly combined, could also produce white light. RGB LED luminaries are, for example, used in LCD back lighting, commercial-freezer lighting, and white light illumination.

In order to shift the color in an RGB LED setup, dimming by e.g. continuous current reduction or pulse-width-modulation (PWM) is required. Furthermore, color and output variations from one light emitting diode to the next may become very obvious. Because of this, color mixing by dimming is typically inefficient and impractical for many color mixing applications.

There is thus a need in the art to provide a light emitting device, wherein the color of the output light could be more easily shifted and varied for different applications.

### SUMMARY OF THE INVENTION

One object of the present invention is to fulfill the above mentioned need and to provide a light emitting device which provides for an easy color variation control which overcomes the drawbacks described above.

This and other objects of the present invention are achieved by a light-emitting device according to the appended claims.

Thus, in a first aspect the present invention relates to a color variable light-emitting device comprising at least one light source and at least one deformable element. The deformable element comprises particles of at least one wavelength converting material and is arranged to receive light from the at least one light source and to convert it into light of a different wavelength.

In a device of the present invention, light that is emitted by the light source at oblique angles will encounter the particles of wavelength converting material(s) and be scattered and converted into light of a different wavelength. Since the element comprising the wavelength converting material(s) is deformable, the thickness of the element can be varied. This thickness variation allows for the wavelength converting material, and hence also the color, to be “tuned”. Hence, a large degree of design and aesthetic freedom is obtained and the color of the output light may be easily shifted.

In embodiments of the invention the deformable element comprises a gel. The gel increases the deformability of the element, which in turn results in that the thickness of the element, and thereby the color output can be more easily varied.

The combination of gel and wavelength converting material(s) within the deformable element also allows for light to be emitted from the total volume of the deformable element.

Typically, the gel comprises silicone. Silicone is a flexible, inert and thermally stable material.

In one embodiment of the invention, the at least one light source is arranged in the deformable element. In this embodiment the deformable element essentially encloses the light source(s) and the light source is thus surrounded by the particles of wavelength converting material dispersed therein.

One advantage with this arrangement is that light is efficiently converted due to the constant encounter with particles of wavelength converting material. Light which is scattered in a backwards direction; i.e. back towards the light source is not lost, but is instead efficiently converted.

In another embodiment of the color variable light emitting device according to the present invention, the at least one light source is arranged at a distance from said deformable element. In this embodiment the light source may be placed at a distance from the deformable element providing a so-called “remote phosphor” application. The use of wavelength converting material; i.e. phosphor that is not directly attached to the LED alleviates the requirements with respect to temperature and light flux that the wavelength converting material can withstand. Therefore, this so-called remote phosphor embodiment allows for a low color temperature and a good color rendering index. Furthermore, the light quality (unpleasant peak brightness, color control) may be improved and the color may be controlled by varying the properties of the wavelength converting material(s).

In embodiments where the light source is arranged at a distance from the deformable element, it is advantageous to use a light guide to guide the light that is emitted by the light source into the deformable element, allowing for the light to contact the particles of wavelength converting material(s). The light guide can be used both for guiding the light from the light source to the particles of wavelength converting material(s) and for capturing and recycling light that returns from the wavelength converting material(s).

In yet another embodiment of the present invention, the color variable light emitting device comprises at least a first deformable element and a second deformable element. The second deformable element is arranged to receive at least part of the light emitted by the light source(s) which has passed through the first deformable element. By combining two or more deformable elements, mixed colors may be generated and the color may be varied in general or locally by varying the thickness of the deformable element(s).

The first deformable element may comprise a first wavelength converting material and the second deformable element may comprise a second wavelength converting material. This way multiple colors may be obtained.

In embodiments of the invention, the color variable light emitting device further comprises a device for varying the thickness of the deformable element. Such a device might be a magnetic or a thermal activator. However, the thickness can also be varied simply by using a human finger. This is beneficial since a “personalized” deformable element that emits different colors may be obtained.

These and other aspects of the invention will be apparent from and elucidated with reference to the embodiment(s) described hereinafter.

### BRIEF DESCRIPTION OF THE DRAWINGS

FIG. 1a schematically illustrates a first embodiment of a color variable light emitting device according to the present invention, wherein the light source is arranged in the deformable element.

FIG. 1b schematically illustrates a second embodiment of a color variable light emitting device according to the present invention, wherein the light source is arranged at a distance from the deformable element.

FIG. 2 schematically illustrates a color variable light emitting device according to one embodiment of the present invention in which a lightguide is used.

FIG. 3 schematically illustrates an embodiment of a color variable light emitting device according to the present invention comprising two deformable elements and two light sources.

FIG. 4 is a principle setup of a color variable light emitting device according to the present invention which emits light from a 2D surface.

### DETAILED DESCRIPTION OF THE EMBODIMENTS

The present invention relates to a color variable light emitting device comprising at least one light source and at least one deformable element, wherein said deformable element comprises particles of at least one wavelength converting material.

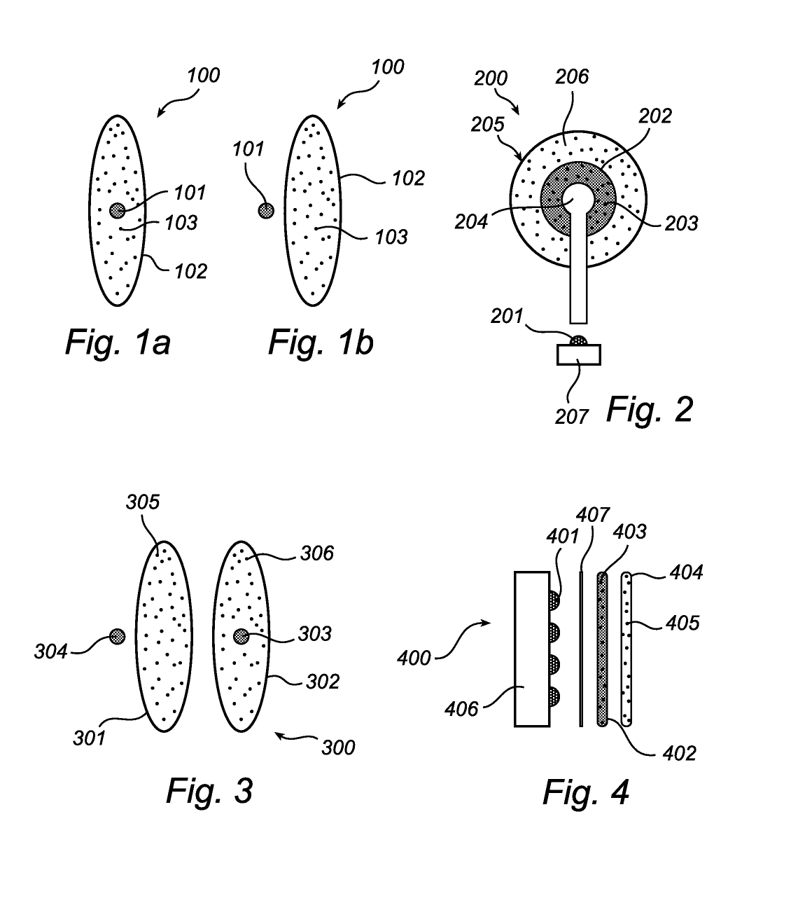

One embodiment of a color variable light emitting device 100 according to the present invention is illustrated in FIG. 1. The color variable light emitting device 100 comprises at least one light source 101 and a deformable element 102. The deformable element 102 comprises particles of at least one wavelength converting material 103 which are dispersed within the deformable element 102. The deformable element 102 is arranged to receive light from the light source 101.

As used herein, the term “light source” may be any source of light, but in this context it typically refers to one or more light emitting diode(s) (LEDs). LEDs are advantageously used due to their small size, potential energy savings and long life.

Light emitted by the light source 101 is received by the deformable element 102 and the wavelength converting particles 103 comprised therein will convert at least part of the light into light of a different wavelength.

The deformable element 102 thereby serves as a wavelength converting element.

As used herein the term “wavelength converting” refers to a material or an element that absorbs light of a first wavelength resulting in the emission of light of a second, longer wavelength. Upon absorption of light, electrons in the material become excited to a higher energy level. Upon relaxation back from the higher energy levels, the excess energy is released from the material in form of light having a longer wavelength than of that absorbed. Hence, the term relates to both fluorescent and phosphorescent wavelength conversion.

The deformable element 102 is temperature, oxidation and radiation stable and will not deteriorate when exposed to heat, oxygen and/or light.

The term “deformable element” refers to an element formed from a highly flexible material, the element being bendable and plastic such that the thickness of the element may be varied, either locally or in general.

Upon contact with the particles 103 in the deformable element, light will be scattered in different direction and the light emerging from the deformable element 102 has been efficiently converted by the particles of wavelength converting material(s) 103. Furthermore, light is emitted from the total volume of the deformable element 102 and not only from its outer surface.

Typically, the deformable element 102 comprises a gel to further increase the deformability and the flexibility of the element such that the thickness of the element may easily be varied, either locally or in general.

The gel preferably comprises silicone which is heat-resistant and inert and thereby suitable for use in the color variable light emitting device of the present invention. The present invention is not limited to the use of silicone, but several other deformable materials, e.g. highly viscose organic material may also be used and these are known to a person skilled in the art.

Preferably the gel, and thus also the deformable element is optically clear, meaning that it can be seen through, i.e. it allows clear images to pass.

In embodiments of the invention, the light source(s) may be arranged either in the deformable element or at a distance from the deformable element.

According to the embodiment illustrated in FIG. 1a, the at least one light source 101 is arranged in the deformable element 102. As mentioned, one advantage with this arrangement is that light is efficiently converted due to the constant encounter with particles of wavelength converting material 103 surrounding the light source 101. Light which is scattered in a backward direction; i.e. back towards the light source 101 is not lost, but will instead be efficiently converted.

In another embodiment of the color variable light emitting device 100 according to the invention, which is illustrated in FIG. 1b, the at least one light source 101 is arranged at a distance from the deformable element 102.

In this embodiment the light source 101 may be placed remote from the deformable element 102 providing a so called “remote phosphor” application. In traditional LEDs the wavelength converting material; i.e. the phosphor is embedded in glue that is directly attached to the chip. In this construction the wavelength converting material has to withstand the temperature of the LED and the light flux at the same time. The use of wavelength converting material that is not directly attached to the LED alleviates the requirements with respect to temperature and light flux that the wavelength converting material can withstand. Therefore, this so-called remote phosphor embodiment allows for a low color temperature and a good color rendering index. Furthermore, the light quality (unpleasant peak brightness, color control) may be improved and the color may be controlled by varying the properties of the wavelength converting material(s). Furthermore, a luminaire manufacturer can choose the color independently of the LED(s).

The deformable element 102 comprising wavelength converting material particles 103 serves as a wavelength converting element and is self-supporting. Such a self-supporting deformable element 102 can be mass produced in bulk, complete with the particles of wavelength converting material 103 comprised therein, and may then at a later stage be combined with the light source 101.

In embodiments where the light source is arranged at a distance from the deformable element, a light guide may be used, and a color variable light emitting device 200 according to this embodiment of the invention is illustrated in FIG. 2.

Light emitted by the light source 201 is received by the light guide 204, which serves to guide the emitted light into the deformable element 202. Upon contact with the particles of wavelength converting material(s) 203 dispersed within the deformable element 202, light is efficiently converted into light of a different wavelength. Hence, the light guide 204 has two different purposes; i.e. to guide the light from the light source 201 to the particles of wavelength converting material(s) 203 and to capture and recycle light that returns from the deformable element 202.

In some embodiments, the color variable light emitting device 200 may comprise more than one deformable elements. Hence, a second deformable element 205 may be arranged to receive at least part of the light emitted by the light source 201 which has passed through the first deformable element 202.

The combination of two or more deformable elements allows for the color to be varied in general or locally by varying the thickness of either or both of the deformable elements.

Typically in this embodiment, multiple wavelength converting materials are used allowing for the generation of mixed colors. For example, the first deformable element 202 may comprise a first wavelength converting material 203 and the second deformable element 205 may comprise a second wavelength converting material 206. Alternatively, the deformable elements comprise a mixture of more than one wavelength converting materials. Accordingly multiple and mixed colors may be obtained and different colors may be generated by simply varying the thickness of the element(s).

Optionally, a heat sink 207 can be arranged to transport heat away from the light emitting device 200.

Referring now to FIG. 3, a color variable light emitting device 300 comprising a first deformable element 301 and a second deformable element 302 is illustrated. The second deformable element 302 is arranged to receive at least part of the light which has passed through the first deformable element 301.

The present invention is not limited to a certain number of light sources or a specific arrangement thereof Instead, many light sources may be used and these may be arranged either in and/or at a distance from the deformable elements. For example, it is possible to arrange a first light source 303 in the deformable element(s) and a second light source 304 at a distance from the deformable element(s). The light source may also be arranged to emit light only in one of the deformable elements.

The deformable elements 301 and 302 may comprise different types of wavelength converting material particles 305 and 306.

FIG. 4 is a principle setup of a color variable light emitting device 400 according to the present invention which emits light from a 2D surface.

In this embodiment, the color variable light emitting device 400 comprises at least one light source 401, a first deformable element 402 comprising at least one wavelength converting material 403, said first deformable element 402 being arranged to receive at least part of the light emitted by the light source 401. A second deformable element 404 is arranged to receive light which has passed through the first deformable element 402. The second deformable element 403 may comprise at least one wavelength converting material 405 which may be the same or different from the wavelength converting material 403 of the first deformable element 402.

In embodiments of the invention, additional optics, such as for example a heat sink 406 is arranged to transport heat away from the light emitting device 400. Furthermore, a diffusor 407 may be arranged to receive light emitted by the light source(s) 401 in order to generate a homogenous and diffuse light output.

In embodiments of the invention, the color variable light emitting device further comprises a device for varying the thickness of the deformable element. Such a device might be a magnetic or a thermal activator, which affects the thickness of the deformable element through magnetism or heat. It is also possible to vary the thickness of the deformable element(s) simply by using a human finger. This relatively easy thickness control is beneficial since a “personalized” deformable element that emits different colors may be obtained.

When the deformable element is locally deformed, this local deformation could be used to activate a function of another device, e.g. with the help of an electrical current. At the same time, the deformed element can provide feedback to the user which area was last touched by simply showing the local deformation.

The color variable light emitting device according to the present invention may be used in several applications, e.g. in a tactile product. It may also be utilized in touch screens, mobile phones, pillows, waterbeds, pressure meters etc.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. For example, the present invention is not limited to the use of a specific light source although LED(s) are typically used. Neither is the invention limited to a specific type of LED, but any type of LED with any color or wavelength combination may be used.

1. A color variable light emitting device comprising at least one light source and at least one deformable element, wherein said deformable element comprises particles of at least one wavelength converting material, said element being arranged to receive light from said at least one light source and to convert it into light of a different wavelength.

2. A color variable light emitting device according to claim 1, wherein said deformable element comprises a gel.

3. A color variable light emitting device according to claim 2, wherein said gel comprises silicone.

4. A color variable light emitting device according to claim 1, wherein said at least one light source is arranged in said deformable element.

5. A color variable light emitting device, according to claim 1, wherein said at least one light source is arranged at a distance from said deformable element.

6. A color variable light emitting device according to claim 5, further comprising a light guide arranged to guide at least part of the light emitted by said light source into, said deformable element.

7. A color variable light emitting device according to claim 1 comprising a first deformable element and a second deformable element, wherein said second deformable element is arranged to receive at least part of the light emitted by said at least one light source which has passed through said first deformable element.

8. A color variable light emitting device according to claim 7, wherein said first deformable element comprises a first wavelength converting material and said second deformable element comprises a second wavelength converting material.

9. A color variable light emitting device according to claim 1 further comprising a device for varying the thickness of said deformable element.
